(19) United States
(12) Patent Application Publication
(10) Pub. No.: US 2013/0055954 A1
(43) Pub. Date: Mar. 7, 2013

(54) INTEGRATED SEMICONDUCTOR-PROCESSING APPARATUS

(71) Applicant: Jeong-Ho Yoo, Suwon-si (KR)

(72) Inventor: Jeong-Ho Yoo, Suwon-si (KR)

(21) Appl. No.: 13/696,529

(22) PCT Filed: May 6, 2011
(86) PCT No.: PCT/KR2011/003411

§ 371 Date: Nov. 6, 2012

(30) Foreign Application Priority Data
May 7, 2010 (KR) 1020100042747
May 6, 2011 (KR) 21020110043022

(51) Int. Cl. H01L 21/677; H01L 21/30

(52) U.S. Cl. 118/728; 414/222.01

(57) ABSTRACT

The present invention relates to an integrated semiconductor-processing apparatus including: an integrated semiconductor-processing body which has a first space for storing a plurality of FOUPs containing a plurality of wafers, and a second space in which a processing device is installed to process the wafers stored in the first space; a load port module installed in the first space of the integrated semiconductor-processing body to open the FOUPs to enable extraction of wafers from the FOUPs; and a transfer device which extracts wafers from the FOUPs and transfers the wafers to the processing device in the second space.

### TECHNICAL FIELD

The present invention relates to a technique for supplying a semiconductor wafer to a heat-treatment process to heat-treat the semiconductor. More particularly, the present invention relates to a technique which can minimize the length of a transfer line along which a wafer is transferred from a space where it has been stored to a wafer processing device and which can minimize the wafer from being exposed to the outside when the wafer is supplied to the wafer processing device.

### BACKGROUND ART

Generally, as advances in semiconductor technology accelerate, researches into techniques for processing wafers required to produce semiconductors become active. A wafer is a slice of material which is used to produce a semiconductor. A silicon wafer undergoes different kinds of processing steps before it is provided as a material used in fabrication of a semiconductor.

The silicon wafer is a circular thin plate which is formed by slicing a cylindrical ingot that is formed by growing a crystal of the same kind of material as that of the silicon semiconductor. In the process of growing the crystal to produce silicon wafers, oxygen combines with the silicon wafers. Such impurities formed on a silicon wafer cause a controlled resistance value to become different from a desired resistance value.

Therefore, a heat-treatment process is required to remove oxygen from the wafer and produce a high quality wafer. Furthermore, the heat-treatment process is also required to mitigate machining stress or reduce defects of a wafer crystal.

Productivity and production yield are important factors which concern the process of heat-treating a wafer. Enhancing production yield, in other words, producing a high quality wafer, is an obvious purpose of the wafer heat-treatment. Along with this, it is necessary to be able to rapidly heat-treat wafers and produce a large quantity of heat-treated wafers.

### DISCLOSURE

### Technical Problem

Accordingly, the present invention has been made keeping in mind the above problems occurring in the prior art, and an object of the present invention is to provide an integrated semiconductor-processing apparatus which is used in a process of heat-treating a silicon wafer to produce a semiconductor and is configured such that the distance that the wafer is transferred is minimized, thus reducing the time for processing the wafer, thereby increasing the heat-treated wafer production rate. Another object of the present invention is to provide an integrated semiconductor-processing apparatus which can minimize spatio-temporal exposure of the wafers to the outside, thus enhancing production yield in heat-treatment. A further object of the present invention is to provide an integrated semiconductor-processing apparatus in which components are appropriately combined with each other in three dimensions to form a compact structure so that the space required to install the apparatus in a plant can be reduced.

### Technical Solution

In order to accomplish the above object, the present invention provides an integrated semiconductor-processing apparatus including: an integrated semiconductor-processing body having a first space for storing a plurality of FOUPs containing a plurality of wafers, and a second space in which a processing device is installed to process the wafers stored in the first space; a load port module installed in the first space of the integrated semiconductor-processing body, the load port module opening the FOUPs to enable the wafers to be extracted from the FOUPs; and a transfer device extracting wafers from the FOUPs and transferring the wafers to the processing device in the second space.

The first space may store one to forty FOUPs.

The load port module may comprise a plurality of load port modules installed in the first space, wherein at least one of the load port modules may transfer a wafer, which has been stored in the corresponding FOUP and is unprocessed, to the processing device, and a remaining one of the load port modules may transfer a wafer that has been processed by the processing device to the FOUP so that the wafer can be stored in the FOUP again.

The integrated semiconductor-processing apparatus may further include a FOUP transfer robot installed in the first space to transfer at least one of the FOUPs between a stored location thereof and the load port module.

The FOUP transfer robot may include: a transfer arm holding and lifting the FOUP; and an arm rotating unit rotating the transfer arm.

The FOUP transfer robot may include a transfer arm holding and lifting the FOUP. The transfer arm may comprise transfer arms respectively provided at front and rear sides.

The processing device may comprise one selected from among a heat treatment device for heat-treating the wafers, an etcher, and a vapor deposition device.

Furthermore, a space partition wall may be provided in the integrated semiconductor-processing body. The space partition wall may separate the first space from the second space. A connection opening may be formed in the space partition wall. The connection opening may communicate the first space with the second space so that the wafers that have been stored in the FOUPs are supplied from the first space to the processing device in the second space.

In addition, an opening door may be provided in the integrated semiconductor-processing body to openably close the connection opening.

### ADVANTAGEOUS EFFECTS

According to the present invention, components which are used to process wafers can be integrated in a single apparatus, thus minimizing the length of a transfer line along which the wafers are transferred, thereby decreasing processing time. Furthermore, spatio-temporal exposure of the wafers to the outside can be minimized, thus enhancing wafer processing yield. Moreover, the components that are used to process wafers are compactly assembled together in three dimensions, so that the space required to install the semiconductor-processing apparatus in a plant can be minimized.

### DESCRIPTION OF DRAWINGS

FIG. 1 is a perspective view of an integrated semiconductor-processing apparatus, according to an embodiment of the present invention;

FIG. 2 is a side view of the integrated semiconductor-processing apparatus according to the embodiment of the present invention;

FIGS. 3 through 6 are plan views illustrating an embodiment of a FOUP transfer robot according to the present invention;

FIG. 7 is a perspective view of an embodiment of a load port module, according to the present invention;

FIG. 8 is a sectional view showing the construction of the load port module according to the present invention;

FIG. 9 is a schematic view showing the internal construction of an integrated semiconductor-processing apparatus, according to another embodiment of the present invention; and

FIGS. 10 and 11 are plan views showing an integrated semiconductor-processing apparatus, according to a further embodiment of the present invention.

### DESCRIPTION OF THE ELEMENTS IN THE DRAWINGS

10: integrated semiconductor-processing body 11: first space

12: second space 20: load port module

30: transfer device 40: processing device

50: FOUP transfer robot

### BEST MODE

Hereinafter, a preferred embodiment of the present invention will be described in detail with reference to the attached drawings.

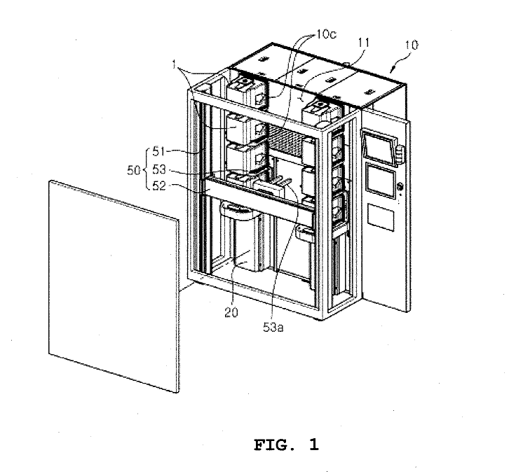

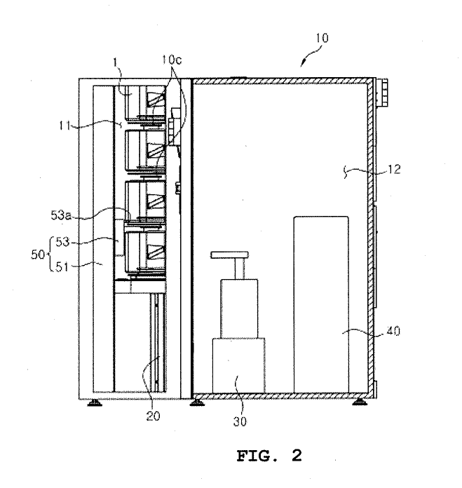

Referring to FIGS. 1 and 2, an integrated semiconductor-processing apparatus according to the present invention includes an integrated semiconductor-processing body 10 which has a first space 11 and a second space 12.

The first space 11 and the FOUPs 1 form anoxic conditions to prevent loss of wafers. For example, the first space 11 and the FOUPs 1 may be filled with nitrogen so that the wafers are prevented from combining with oxygen.

The shape of each FOUP 1 is that of a casing which has on one side thereof a door 1a so that the casing is openably closed by the door 1a.

The FOUP 1 can store wafers that are targets to be processed or that have been processed. Wafers that have been processed by a processing device 40 can also be stored in the first space 11.

Therefore, the multiple FOUPs 1 which store not only non-processed wafers but also processed wafers can be contained together in the first space 11. For instance, the first space 11 which contains the FOUPs 1 are partitioned into a first section and a second section, and the first space contains a plurality of FOUPs 1 that store non-processed wafers while the second space contains a plurality of FOUPs 1 that store processed wafers.

The first space 11 generally contains one to forty FOUPs 1.

In an embodiment of the present invention, the first section has a parallelepiped structure. The FOUPs 1 may be provided on the inner sidewalls of the first section in such a way that a predetermined number of FOUPs 1 are disposed on each of several portions and are stacked on top of one another. In other words, the FOUPs 1 may be arranged in the first space 11 in multiple rows in each of which a predetermined number of FOUPs 1 are stacked on top of one another. For example, the FOUPs 1 are stacked on top of one another at each of both sides of one sidewall of the first space 11 on which load port modules 20 that are installed in a lower portion of the first section are disposed. In more detail, the load port modules 20 are respectively installed at both sides of the lower portion of the first space 11. FOUPs 1 are stacked on top of one another above each of the load port modules 20, and FOUPs 1 are arranged in multiple rows between the load port modules 20. The detailed shape of this is illustrated in FIG. 1.

Mounts 10c such as racks or frames which support the FOUPs 1 are provided in the first space 11 so that the FOUPs 1 can be easily stored in the first space 11. In this embodiment, the mounts 10c which can support the FOUPs 1 are provided on an upper portion of a front surface of a space partition wall 13 which is disposed in the first space 11. The load port modules 20 are disposed in the lower portion of the first space 11 to open the FOUPs 1 and allow the wafers to be extracted from the FOUPs 1.

Preferably, the present invention further includes a FOUP transfer robot 50 which is installed in the first space 11 and transfers a FOUP 1 between its stored location and the corresponding load portion module 20.

The FOUP transfer robot 50 includes a means for supporting a FOUP 1 and a means for transferring the FOUP 1. The means for transferring can move forward, rearward, upward, downward, leftward, and rightward to transfer the FOUP 1 between its stored location and the corresponding load port module 20.

The FOUP transfer robot 50 includes a vertical transfer guide rail 51, a horizontal transfer guide rail 52 and a FOUP holder 53. The vertical transfer guide rail 51 is disposed in the first space 11 and is vertically oriented. The horizontal transfer guide rail 52 is disposed in the first space 11 and is horizontally oriented. The horizontal transfer guide rail 52 is connected to the vertical transfer guide rail 51 such that it can be vertically moved along the vertical transfer guide rail 51 by a separate drive device. The FOUP holder 53 is connected to the horizontal transfer guide rail 52 such that it can be moved to the left or the right along the horizontal transfer guide rail 52 by a separate drive device. The FOUP holder 53 separates the FOUP 1 from its stored location and transfers it to the load port module 20.

In an embodiment, the FOUP holder 53 includes a plurality of transfer arms 53a which protrude toward the FOUPs 1. The transfer arms 53a support the bottom of a FOUP 1 so that the FOUP holder 53 can lift the FOUP 1 and then transfer it to the load port module 20. Although it is not illustrated, the FOUP holder 53 may include a clamping unit which clamps the FOUP 1 so that the FOUP holder 53 can lift the FOUP 1 and transfer it.

The FOUP holder 53 moves along the horizontal transfer guide rail 52 to the left or the right. The FOUP holder 53 can also move upward or downward as the horizontal transfer guide rail 52 moves upward or downward along the vertical transfer guide rail 51. As a result, the FOUP holder 53 can move upward, downward, leftward, and rightward. This makes it easy for the FOUP holder 53 to transfer the FOUPs 1 that are stored in the first space 11 to the load port module 20.

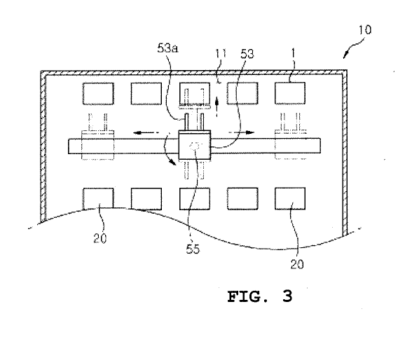

Referring to FIG. 3, the FOUP transfer robot 50 may include a horizontal transfer guide rail 52 which is disposed in the first space 11 and is horizontally oriented, and a FOUP holder 53 which is connected to the horizontal transfer guide rail 52 such that it can be moved to the left or the right along the horizontal transfer guide rail 52 by a separate drive device. The FOUP holder 53 functions to separate the FOUP 1 from its stored location and transfer it to the load port module 20.

The FOUP holder 53 includes a transfer arm 53a which protrudes toward the FOUPs 1 and is configured such that it is able to lift a FOUP 1.

Furthermore, the transfer arm 53a is provided so as to be movable forward and backward.

The FOUP transfer robot 50 further includes an arm rotating unit 55 which rotates the FOUP holder 53.

In the FOUP transfer robot 50, the FOUP holder 53 is moved to the left or the right along the horizontal transfer guide rail 52 and positioned corresponding to a target FOUP 1. Thereafter, the FOUP holder 53 moves the transfer arm 53a toward the FOUP 1, holds the FOUP 1, and lifts it. Subsequently, the FOUP transfer robot 50 transfers the FOUP 1 to the load port module 20.

Furthermore, the FOUP transfer robot 50 can rotate the FOUP holder 53, so that it can lift the FOUPs 1 that are disposed ahead of and behind the FOUP holder 53 and then transfer them to the load port module 20.

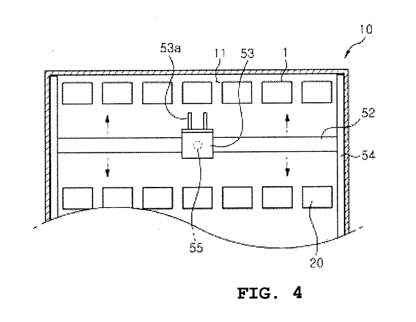

Referring to FIG. 4, the FOUP transfer robot 50 may include a forward-backward transfer guide rail 54, a horizontal transfer guide rail 52, and a FOUP holder 53. The forward-backward transfer guide rail 54 is disposed in the first space 11 and oriented in a forward-backward direction. The horizontal transfer guide rail 52 is disposed in the first space 11 and oriented in a left-right direction. The horizontal transfer guide rail 52 is connected to the forward-backward transfer guide rail 54 such that it can be moved forward or backward along the forward-backward transfer guide rail 54 by a separate drive device. The FOUP holder 53 is connected to the horizontal transfer guide rail 52 such that it can be moved to the left or the right along the horizontal transfer guide rail 52 by a separate drive device. The FOUP holder 53 separates a FOUP 1 from its stored location and transfers it to the load port module 20.

Furthermore, the FOUP holder 53 includes a transfer arm 53a which protrudes toward the FOUPs 1 to lift a FOUP 1.

The FOUP transfer robot 50 further includes an arm rotating unit 55 which rotates the FOUP holder 53.

In the FOUP transfer robot 50, the FOUP holder 53 is moved to the left or the right along the horizontal transfer guide rail 52 and positioned at a position corresponding to a desired FOUP 1. Thereafter, the horizontal transfer guide rail 52 moves toward the FOUP 1 so that the FOUP holder 53 holds the FOUP 1 and lifts it. Subsequently, the FOUP transfer robot 50 transfers it to the load port module 20.

Furthermore, the FOUP transfer robot 50 can rotate the FOUP holder 53, so that it can lift the FOUPs 1 that are disposed ahead of and behind the FOUP holder 53 and then transfer them to the load port module 20.

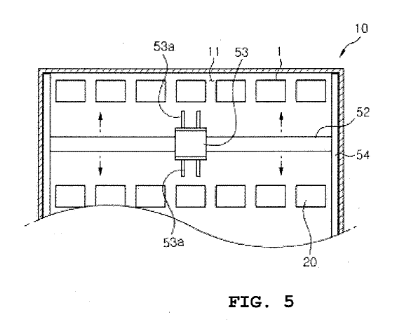

Referring to FIG. 5, the FOUP holder 53 may include transfer arms 53a which respectively protrude forward and rearward therefrom to lift the FOUPs 1.

In this case, the transfer arms 53a that are respectively provided on the front and rear sides of the FOUP holder 53 can lift the FOUPs 1 that are disposed ahead and behind the FOUP holder 53 and then transfer them to the load port module 20.

As such, the FOUP transfer robot 50 may include the single arm type of transfer arm 53a which lifts the FOUP 1. In this case, the FOUP transfer robot 50 further includes the arm rotating unit 55 which rotates the transfer arm 53a so that it can lift the FOUPs 1 that are disposed at the front and rear positions and then transfer them to the load port module 20.

Alternatively, the FOUP transfer robot 50 may include the double arm type of transfer arm 53a which lifts the FOUP 1. In this case, the transfer arm 53a comprises the two transfer arms 53a which are respectively provided at the front and rear sides so that the transfer arms 53a can lift FOUPs 1 that are disposed at the front and rear positions and then transfer them to the load port module 20.

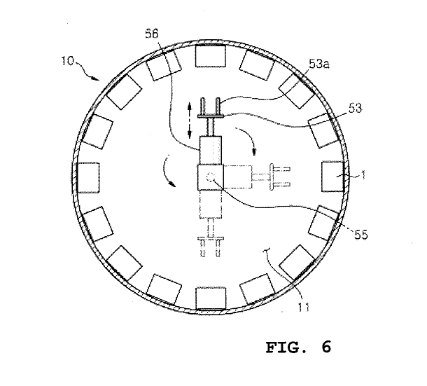

Referring to FIG. 6, the FOUP transfer robot 50 may include a FOUP holder 53 which separates a FOUP 1 from its stored location and transfers it to the load port module 20, a forward-backward device 56 which transfers the FOUP holder 53 forward or backward, and an arm rotating unit 55 which rotates the forward-backward device 56 and the FOUP holder 53.

In this FOUP transfer robot 50, the FOUP holder 53 is configured such that it is rotated around the arm rotating unit 55 and is moved forward or backward by the forward-backward device 56 so that it can lift any one of the FOUPs 1 that are arranged in a circle and then transfer it to the load port module 20.

With reference to FIG. 2 again, the integrated semiconductor-processing apparatus according to the present invention will be explained.

To enhance efficiency of processing the FOUPs 1, they may be stacked on top of one another in such a way that the casings open toward the second space 12. For example, as shown in FIG. 2, the second space 12 may be formed behind the first space 11. The wafers are transmitted to and processed in the processing device 40 that is installed in the second space 12. Therefore, to directly supply the wafers from the load port module 20 to the processing device 40, the FOUPs 1 are stacked on top of one another such that the direction in which the FOUPs 1 open is oriented toward the second space 12. Of course, the FOUPs 1 may be stacked on top of one another such that they open in other directions.

For instance, the FOUPs 1 may be stacked on top of one another at each side of the inner walls of the first space 11, and each FOUP 1 may be oriented in any direction. In this case, the manner in which the FOUP transfer robot 50 moves may be modified to have more various structures, rather than being limited to the above embodiments, so that regardless of the orientations of the FOUPs 1, the FOUP transfer robot 50 can transfer the FOUPs 1 between their stored locations and the load port module 20.

The anoxic conditions are created in the first space 11 to prevent damage to the wafers, because oxygen may damage the wafers. For this, a nitrogen supply device may be provided in the first space 11 so that the first space 11 and the FOUPs 1 can be filled with nitrogen.

The load port module 20 is disposed in the lower portion of the first space 11. The load port module 20 has space in which it can support the FOUP 1, so that after the FOUP 1 is placed on the load port module 20, the load port module 20 opens or closes it. After the load port module 20 has opened the FOUP 1, an unprocessed wafer may be transferred from the FOUP 1 to the processing device 40, or a processed wafer may be transferred from the processing device 40 to the FOUP 1.

To supply the FOUP 1 to the processing device 40, the load port module 20 may function to open the FOUP 1 that has been transferred by the FOUP transfer robot 50 and then extract the wafer out of the FOUP 1. Alternatively, a wafer transfer robot of a transfer device 30 may directly enter the load portion module 20 and extract the wafer therefrom.

In an embodiment of the present invention, the load port module 20 may comprise a plurality of load port modules 20 which are disposed on one side of the lower portion of the first space 11. Here, the one side of the lower portion of the first space 11 may be the same side as that of the inner wall of the first space 11 at which the FOUPs 1 are stacked on top of one another. Further, the load port module 20 may be disposed at any location, so long as it can transfer the wafer along a series of wafer transfer paths that are connected to the transfer device 30 and the processing device 40.

The load port modules 20 may be provided, and at least one of them functions to transfer an unprocessed wafer from the FOUP 1 to the processing device, while another functions to transfer the wafer, which has been processed by the processing device 40, to the FOUP 1 so that the wafer can be stored in the FOUP 1 again.

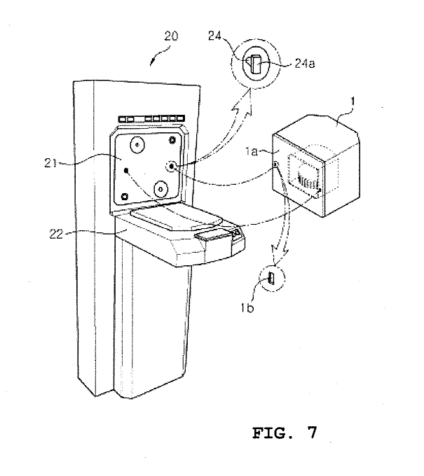

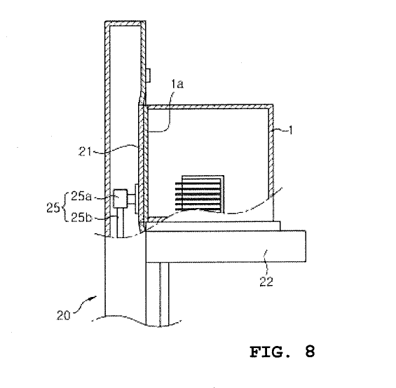

Referring to FIGS. 7 and 8, an example of the load port module 20 includes a movable panel 21 which is provided with a door opening/closing means which opens or closes a transfer path opening and the FOUP 1, and a FOUP support 22 which is disposed below the movable panel 21 and supports the FOUP 1 thereon.

The door opening/closing means includes a rotating shaft 24 and a panel lift device 25. The rotating shaft 24 protrudes from a front surface of the movable panel 21 that faces the FOUP 1 and has a locking hook 24a on an end thereof which is inserted into a locking hole 1b formed in a door 1a of the FOUP 1 to open or close the door 1a. The rotating shaft 24 is rotated by a separate drive means. The panel lift device 25 is connected to the movable panel 21 and vertically moves the movable panel 21.

The panel lift device 25 includes a panel moving unit 25a which is connected to the movable panel 21 and moves the movable panel 21 forward or backward, and a panel lift unit 25b which is connected to the panel moving unit 25a and moves the movable panel 21 upward or downward.

The load port module 20 conducts the following operation to open the door 1a of the FOUP 1.

The FOUP 1 is placed on the upper surface of the FOUP support 22 so that the door 1a of the FOUP 1 comes into close contact with the movable panel 21. Subsequently, the locking hook 24a provided on the end of the rotating shaft 24 of the door opening/closing means is inserted into the locking hole 1b formed in the door 1a of the FOUP 1. When the rotating shaft 24 inserted into the locking hole 1b is rotated, the door 1a of the FOUP 1 is released from the closed state.

To prevent the movable panel 21 and the door 1a of the FOUP 1 that is brought into close contact with the movable panel 21 from being blocked by other elements when the panel lift device 25 moves the movable panel 21 and the door 1a downward, the panel moving unit 25a moves them backward before the panel lift unit 25b moves them downward.

The FOUP 1 opens in such a way that both the movable panel 21 and the door 1a of the FOUP 1 are moved downward by the panel lift device 25.

The load port module 20 is not limited to the above example, and can be modified in a variety of manners as long as it can open and close the door 1a of the FOUP 1.

Referring to FIG. 2, the second space 12 is a wafer processing space which contains the processing device 40 which processes the wafers that have been stored in the first space 11.

The processing device 40 is a device which processes a wafer, for example, it may be a heat treatment device which heat-treats the wafer, a vapor deposition device such as a CVD (Chemical Vapor Deposition) device, or an etcher.

Furthermore, the transfer device 30 which extracts the wafer from the FOUP 1 and transfers it the processing device in the second space 12 is installed in the integrated semiconductor-processing body 10.

The transfer device 30 is disposed between the first space 11 and the second space 12 at a position adjacent to a rear surface of the load port module 20. The transfer device 30 extracts the wafer from the FOUP 1 that has been opened by the operation of the load port module 20 and then transfers it to the processing device 40 of the second space.

The transfer device 30 functions to supply the wafer, extracted from the load port module 20, to the processing device 40.

The transfer device 30 must be able to reliably hold the wafer in the load port module 20, extract it from the load port module 20, and precisely transfer it to the processing device 40. Furthermore, the transfer device 30 must be able to extract the processed wafer from the processing device 40 and precisely put it into the FOUP 1 that is disposed in the load port module 20.

A wafer transfer robot is one example of the transfer device 30. To achieve the above purpose, the wafer transfer robot includes a holder which holds the wafer to transfer it from or to the FOUP 1, a transfer means for transferring the wafer, and an aligner which adjusts the position of the wafer to precisely put the wafer into the FOUP 1 or the processing device 40.

One example of the transfer means of the wafer transfer robot may be a robot arm structure which includes a plurality of arms that are rotatably connected to each other by hinges, an arm operating unit which operates the arms so as to be rotatable around the hinges, an arm lift unit which moves the arms upward or downward, and a rotating unit which rotates the arms.

As well as the above example, any structure can be used as the transfer means, so long as it can function to transfer the wafer from the load port module 20 to the processing device 40. For example, the transfer means may be configured such that the holder that holds the wafer is provided so as to be rotatable so that it holds the wafer in the load port module 20 and then transfers it from the load port module 20 to the processing device 40 in such a way so as to rotate. Alternatively, the transfer means may comprise a rail motion means which moves the holder along a rail and supplies the wafer to the processing device 40.

Furthermore, the holder may be configured such that a contact area between it and the wafer is minimized to prevent damage to the wafer. For example, the holder may have a structure in which it supports the wafer thereon with a predetermined number of contact points therebetween.

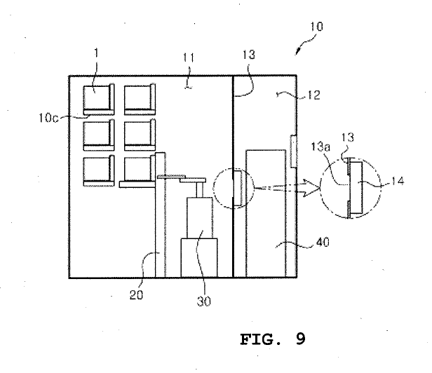

The first space 11 and the second space 12 may communicate with each other in the integrated semiconductor-processing body 10 to form a single space. Referring to FIG. 9, a space partition wall 13 which separates the first space 11 and the second space 12 from each other is provided in the integrated semiconductor-processing body 10. A connection opening 13a is formed in the space partition wall 13. The connection opening 13a communicates the first space 11 with the second space 12 so that the wafer that has been stored in the FOUP 1 can be transferred from the first space 11 to the processing device 40 in the second space 12 through the connection opening 13a. An opening door 14 is provided on the connection opening 13a to open or close it.

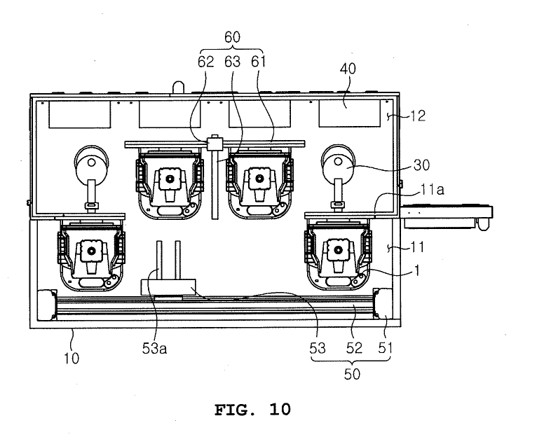

Referring to FIG. 10, the integrated semiconductor-processing apparatus according to the present invention further includes a FOUP moving device 60 which moves some of the FOUPs 1 that are stored in the first space 11 forward or backward.

The FOUP moving device 60 moves some of the FOUPs 1 that are stored in the first space 1 forward or backward, thus providing space in which the FOUP transfer robot 50 can move.

The FOUPs 1 that are moved by the FOUP moving device 60 and the FOUPs 1 that are fixed in the first space 11 are arranged such that their front surfaces are aligned with each other. The FOUP transfer robot 50 is disposed ahead of the FOUPs 1 and can be moved upward, downward, leftward, or rightward so that it can transfer all of the FOUPs 1 that are stored in the first space 11 to the load port module 20.

In other words, the FOUP transfer robot 50 is configured such that the FOUP holder 53 moves to the left or the right along the horizontal transfer guide rail 52 while the horizontal transfer guide rail 52 moves upward or downward along the vertical transfer guide rail 51 so that the FOUP holder 53 can transfer all of the FOUPs 1 stored in the first space 11 to the load port module 20.

The FOUP moving device 60 moves some of the FOUPs 1 stored in the first space 11 rearward, thus forming space required to move the FOUP transfer robot 50 and to transfer the FOUPs 1 to the load port module 20.

Only when space for transferring the FOUPs 1 is required does the FOUP moving device 60 move some of the FOUPs 1 that are stored in the first space 11 rearward. If it is unnecessary to transfer the FOUPs 1 or when the FOUPs 1 are transferred from the FOUP moving device 60 to the load port module 20, the FOUPs 1 remain in their basic locations such that the FOUP transfer robot 50 can lift a selected FOUP 1 and transfer it to the load port module 20.

In an embodiment, the basic position of the FOUP 1 that is moved by the FOUP moving device 60 means its position when it is disposed such that the front surface thereof is aligned with the front surface of the FOUP 1 that is fixed and stored in the first space 11. At this basic position, the FOUP 1 can be caught or clamped by the FOUP transfer robot 50 which moves upward, downward, leftward, and rightward.

That is, multi-rows of FOUPs 1 are arranged in the front portion of the first space 11 between the FOUP transfer robot 50 and the transfer device 30 without making empty space, and only one or two rows of FOUPs 1 are moved rearward by the FOUP moving device 60 so that the space required to move the FOUP transfer robot 50 can be formed.

Thereby, the number of FOUPs 1 that are stored in the first space 11 can be maximized.

The FOUP moving device 60 includes a movable wall 61 which is provided in the first space 11 so as to be movable forward and rearward and to which the corresponding FOUPs 1 are mounted, and a wall moving unit 62 which moves the movable wall 61 forward or rearward.

Preferably, the FOUP moving device 60 further includes a movable-wall-guide rail 63 which is disposed on the bottom of the first space 11 and guides forward or rearward movement of the movable wall 61. A fixed wall 1a to which the FOUPs 1 are mounted is provided in the first space 11. Although it is not shown in the drawings, the wall moving unit 62 may include a wheel which is movably coupled to the movable-wall-guide rail 63, and a motor which rotates the wheel. Alternatively, the wall moving unit 62 may include a screw which is threaded into the movable wall 61, and a motor which rotates the screw.

As a further alternative, the wall moving unit 62 may include a rack, a pinion, and a motor which rotates the pinion. Further, the wall moving unit 62 may include a hydraulic cylinder which is connected to the movable wall 61 so that it can linearly move. As such, the wall moving unit 62 can be realized by a variety of embodiments.

In an embodiment, the movable wall 61 and the fixed walls 1a are installed in the first space 11 at a position spaced apart from the front surface of the integrated semiconductor-processing body 10 such that they are oriented in a transverse direction across the first space 11. The movable wall 61 and the fixed wall 1a partition the first space 11 into a space which stores the FOUPs 1 and a space which contains the transfer device 30.

The movable wall 61 is disposed between the fixed walls 1a. A transfer space for moving the movable wall 61 is defined in the first space 11 behind the movable wall 61 so that the movable wall 61 can move in the transfer space.

The load port module 20 is provided ahead of the fixed walls 1a, and the transfer device 30 is disposed behind the fixed walls 1a.

For example, the fixed walls 1a are fixed to the inner surface of the respective opposite sidewalls of the first space 11, and the movable wall 61 is disposed between the fixed walls 1a.

At least one row of FOUPs 1 is provided on the front surface of each of the fixed walls 1a and the movable wall 61. The transfer device 30 is disposed on the rear surface of each fixed wall 1a. A space is formed behind the movable wall 61 so that the movable wall 61 can move rearward in this space.

Therefore, in this embodiment of the integrated semiconductor-processing apparatus according to the present invention, the FOUPs 1 can be stored in the first space 11 in such a way that they are arranged on the front surfaces of the fixed walls 1a and the movable wall 61 without making empty space. The FOUP transfer robot 50 which transfers the FOUPs 1 are disposed ahead of the arranged FOUPs 1. Thereby, the first space 11 can be most efficiently used so that integrated semiconductor-processing body 10 can be designed to be compact.

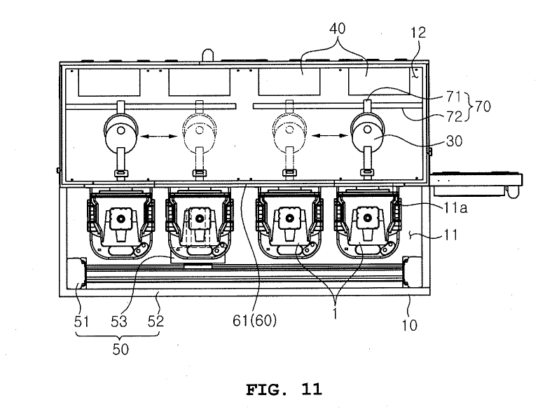

Meanwhile, referring to FIG. 11, the integrated semiconductor-processing apparatus according to the present invention may further include a robot moving device 70 which moves the transfer device 30.

The robot moving device 70 functions to move the transfer devices 30 to the space in which the movable wall 61, that is, the FOUPs 1, moves rearward, so that wafers can be supplied to processing devices 40 that are disposed in this space.

In other words, the robot moving device 70 moves the transfer devices 30 toward the front surfaces of the processing devices 40 that are disposed in the second space 12 so that the wafers can be supplied into the corresponding processing devices 40.

Therefore, in this embodiment of the integrated semiconductor-processing apparatus according to the present invention, the multiple processing devices 40 are arranged in the second space 12 so that the wafer processing speed and the productivity can be enhanced.

In this embodiment, the multiple processing devices 40 are arranged in the transverse direction in the first space 11, and the robot moving device 70 moves the transfer devices 30 in the transverse direction in the first space 11 toward the front surfaces of the corresponding processing devices 40.

The robot moving device 70 includes a drive unit 71 which moves the transfer devices 30. Although it is not shown in the drawings, the drive unit 71 may include a wheel and a motor which rotate the wheel. Alternatively, the drive unit 71 may include a screw which is threaded into each transfer device 30, and a motor which rotates the screw.

As a further alternative, the drive unit 71 may include a rack, a pinion, and a motor which rotates the pinion. Further, the drive unit 71 may include a hydraulic cylinder which is connected to each transfer device 30 so that it can linearly move. As such, the drive unit 71 can be realized by a variety of embodiments.

Preferably, the robot moving device 70 may further include a robot guide rail 72 which guides movement of the device so that it can smoothly move, and precise position control can be realized.

As such, in this embodiment of the integrated semiconductor-processing apparatus according to the present invention, the processing devices 40 can be disposed in the transfer space in which the FOUPs 1 are moved, and the robot moving device 70 can move the transfer devices 30 so that wafers can be transferred to the corresponding devices 40 in the transfer space.

As described above, in the present invention, components which are used to process wafers can be integrated in a single apparatus, thus minimizing the length of a transfer line along which the wafers are transferred, thereby decreasing processing time. Furthermore, spatio-temporal exposure of the wafers to the outside can be minimized, thus enhancing wafer processing yield. Moreover, the components that are used to process wafers are compactly assembled together in three dimensions, so that the space required to install the semiconductor-processing apparatus in a plant can be minimized.

In addition, the integrated semiconductor-processing apparatus can increase the number of FOUPs 1 stored therein, thus enhancing the productivity for wafers, and making it possible to compactly design the arrangement of the semiconductor-processing apparatus in a plant.

Although the preferred embodiments of the present invention have been disclosed for illustrative purposes, the present invention is not limited to the embodiment, and various modifications, additions, and substitutions are possible, without departing from the scope and spirit of the invention.

1. An integrated semiconductor-processing apparatus comprising:
an integrated semiconductor-processing body having a first space for storing a plurality of FOUPs containing a plurality of wafers, and a second space in which a processing device is installed to process the wafers stored in the first space;
a load port module installed in the first space of the integrated semiconductor-processing body, the load port module opening the FOUPs to enable the wafers to be extracted from the FOUPs; and
a transfer device extracting wafers from the FOUPs and transferring the wafers to the processing device in the second space.

2. The integrated semiconductor-processing apparatus as set forth in claim 1, wherein the first space stores one to forty FOUPs.

3. The integrated semiconductor-processing apparatus as set forth in claim 1, wherein the load port module comprises a plurality of load port modules installed in the first space, wherein at least one of the load port modules transfers a wafer, which has been stored in the corresponding FOUP and is unprocessed, to the processing device, and a remaining one of the load port modules transfers a wafer that has been processed by the processing device to the FOUP so that the wafer can be stored in the FOUP again.

4. The integrated semiconductor-processing apparatus as set forth in claim 1, further comprising
a FOUP transfer robot installed in the first space to transfer at least one of the FOUPs between a stored location thereof and the load port module.

5. The integrated semiconductor-processing apparatus as set forth in claim 4, wherein the FOUP transfer robot comprises:
a transfer arm holding and lifting the FOUP; and
an arm rotating unit rotating the transfer arm.

6. The integrated semiconductor-processing apparatus as set forth in claim 4, wherein the FOUP transfer robot comprises a transfer arm holding and lifting the FOUP,
wherein the transfer arm comprises transfer arms respectively provided at front and rear sides.

7. The integrated semiconductor-processing apparatus as set forth in claim 4, further comprising
a FOUP moving device for moving some of the FOUPs that have been stored in the first space forward or rearward.

8. The integrated semiconductor-processing apparatus as set forth in claim 7, wherein the FOUP transfer robot comprises a FOUP holder disposed ahead of the FOUPs in the first space, the FOUP holder moving upward, downward, leftward, or rightward.

9. The integrated semiconductor-processing apparatus as set forth in claim 7, wherein the FOUP moving device comprises:
a movable wall disposed in the first space so as to be movable forward or rearward, with FOUPs mounted to the movable wall; and
a wall moving unit moving the movable wall forward or rearward.

10. The integrated semiconductor-processing apparatus as set forth in claim 9, wherein the FOUP moving device further comprises
a movable-wall-guide rail arranged on a bottom of the first space, the movable-wall-guide rail guiding forward or rearward movement of the movable wall.

11. The integrated semiconductor-processing apparatus as set forth in claim 9, wherein:
fixed walls are provided in the first space, with FOUPs mounted to each of the fixed walls;
the movable wall and the fixed walls are arranged in a transverse direction across the first space so that the movable wall and the fixed walls partition the first space into a space for storing the FOUPs and a space in which the transfer device is disposed;
the movable wall is disposed between the fixed walls; and
the load port module is disposed ahead of the fixed walls, and the transfer device is disposed behind the fixed walls.

12. The integrated semiconductor-processing apparatus as set forth in claim 7, further comprising
a robot moving device for moving the transfer device, and
the processing device comprises a plurality of processing devices disposed in the second space,
wherein the robot moving device moves the transfer device to the front of the processing devices and supplies the wafers to the corresponding processing devices.

13. The integrated semiconductor-processing apparatus as set forth in claim 1, wherein the processing device comprises one selected from among a heat treatment device for heat-treating the wafers, an etcher, and a vapor deposition device.

14. The integrated semiconductor-processing apparatus as set forth in claim 1, wherein a space partition wall is provided in the integrated semiconductor-processing body, the space partition wall separating the first space from the second space, with a connection opening formed in the space partition wall, the connection opening communicating the first space with the second space so that the wafers that have been stored in the FOUPs are supplied from the first space to the processing device in the second space.

15. The integrated semiconductor-processing apparatus as set forth in claim 14, wherein an opening door is provided in the integrated semiconductor-processing body to openably close the connection opening.
